(19) United States
(12) Patent Application Publication
(10) Pub. No.: US 2026/0123103 A1
(43) Pub. Date: Apr. 30, 2026

(54) LIGHT-EMITTING ELEMENT, DISPLAY DEVICE, QUANTUM DOT PRODUCTION METHOD, AND QUANTUM DOT

(71) Applicant: Sharp Display Technology Corporation, Kameyama City, Mie (JP)

(72) Inventor: YOSHIHIRO UETA, Sakai City, Osaka (JP)

(21) Appl. No.: 19/120,571

(22) PCT Filed: Oct. 19, 2022
(86) PCT No.: PCT/JP2022/038900

§ 371 Date: Apr. 11, 2025

(51) Int. Cl. H10H 20/812; H10H 20/01; H10H 20/818; H10H 20/823; H10H 20/824

(52) U.S. Cl. CPC H10H 20/812; H10H 20/012; H10H 20/013; H10H 20/818; H10H 20/823; H10H 20/824

(57) ABSTRACT

A light-emitting element includes: an anode and a cathode; and a quantum dot layer positioned between the anode and the cathode, the quantum dot layer including a first quantum dot and a second quantum dot. The quantum dot layer includes a crystalline body serving as a core of the first quantum dot, and an inorganic amorphous material formed at at least a part of a surface of the crystalline body.

### TECHNICAL FIELD

The disclosure relates to a light-emitting element, a display device, a quantum dot manufacturing method, and a quantum dot.

### BACKGROUND ART

PTL 1 discloses a core-shell particle in which a core particle is coated with a shell containing an inorganic substance, the shell has crystallinity, a secondary particle size is within a range of 3 to 500 nm, and a coverage rate is equal to or more than 80%.

### CITATION LIST

### Patent Literature

PTL 1: WO 2019/131112 A1 (internationally published Jul. 4, 2019)

### SUMMARY

### Technical Problem

There is a demand for improving External Quantum Efficiency (EQE) of a light-emitting element.

### Solution to Problem

According to an aspect of the disclosure, there is provided a light-emitting element including an anode and a cathode, and a quantum dot layer positioned between the anode and the cathode, the quantum dot layer including a first quantum dot and a second quantum dot, wherein the quantum dot layer includes a crystalline body serving as a core of the first quantum dot, and an inorganic amorphous material formed at at least a part of a surface of the crystalline body.

According to an aspect of the disclosure, there is provided a quantum dot manufacturing method including preparing a solution including a core being crystalline, a precursor of a group II-VI compound, and a solvent, and heating the solution, thus causing the precursor to be modified into the group II-VI compound, and then primarily cooling the solution at a rate equal to or more than 100 degrees Celsius/second.

According to an aspect of the disclosure, there is provided a quantum dot having a maximum diameter equal to or less than 100 [nm], the quantum dot including a core being a semiconductor crystal and a shell being an inorganic amorphous material.

### Advantageous Effects of Disclosure

According to one aspect of the disclosure, EQE of the light-emitting element can be improved.

### BRIEF DESCRIPTION OF DRAWINGS

FIG. 1 is a cross-sectional view illustrating an example of a light-emitting element according to an embodiment of the disclosure.

FIG. 2 is a cross-sectional view illustrating an example of a quantum dot layer illustrated in FIG. 1.

FIG. 3 is a cross-sectional view illustrating an example of a region between quantum dots illustrated in FIG. 1.

FIG. 4 is a view illustrating an example of an electron beam diffraction image obtained from a sample in which a crystalline portion and an amorphous portion are mixed in a continuous film.

FIG. 5 is a view illustrating an example of an electron beam diffraction image obtained from a sample in which a crystalline portion and an amorphous portion are mixed in a continuous film.

FIG. 6 is a view illustrating an example of an electron beam diffraction image obtained from a sample in which the crystalline portion and the amorphous portion are mixed in the continuous film.

FIG. 7 is a flowchart illustrating an example of a manufacturing method for the light-emitting element illustrated in FIG. 1.

FIG. 8 is a flowchart illustrating another example of the manufacturing method for the light-emitting element illustrated in FIG. 1.

FIG. 9 is a diagram illustrating an example of a case where an inorganic matrix contains a group II-VI compound in forming the quantum dot layer illustrated in FIG. 1.

FIG. 10 is a diagram illustrating an example of a case where a core contains a group III-V compound and a shell contains a group II-VI compound in forming the quantum dots illustrated in FIG. 1.

FIG. 11 is a diagram illustrating an example of a band structure in a quantum dot of Comparative Example 1.

FIG. 12 is a diagram illustrating an example of the band structure in the quantum dot of Comparative Example 1.

FIG. 13 is a diagram illustrating a crystal system in the quantum dot of Comparative Example 1.

FIG. 14 is a diagram illustrating a crystal system in the quantum dot of Comparative Example 1.

FIG. 15 is a diagram illustrating a crystal system in the quantum dot of Comparative Example 1.

FIG. 16 is a cross-sectional view illustrating a bonding example of a core having a large lattice constant and a shell having a small lattice constant.

FIG. 17 is a graph illustrating relationships between lattice mismatch percentages [%] and critical film thicknesses [nm].

FIG. 18 is a cross-sectional view illustrating a quantum dot layer of Comparative Example 2.

FIG. 19 is a time-series change diagram illustrating a manufacturing method for a quantum dot according to Example of the disclosure.

FIG. 20 is a current density-EQE graph of a light-emitting element according to Example of the disclosure and a light-emitting element of Comparative Example.

FIG. 21 is a voltage-EQE graph of the light-emitting element according to Example of the disclosure and the light-emitting element of Comparative Example.

FIG. 22 is a cross-sectional view illustrating an example of a quantum dot layer according to an embodiment of the disclosure.

FIG. 23 is a time-series change diagram illustrating a quantum dot manufacturing method according to Example of the disclosure.

FIG. 24 is a cross-sectional view illustrating an example of a quantum dot layer according to an embodiment of the disclosure.

FIG. 25 is a schematic view illustrating an example of a display device according to an embodiment of the disclosure.

### DESCRIPTION OF EMBODIMENTS

### First Embodiment

### Configuration of Light-Emitting Element

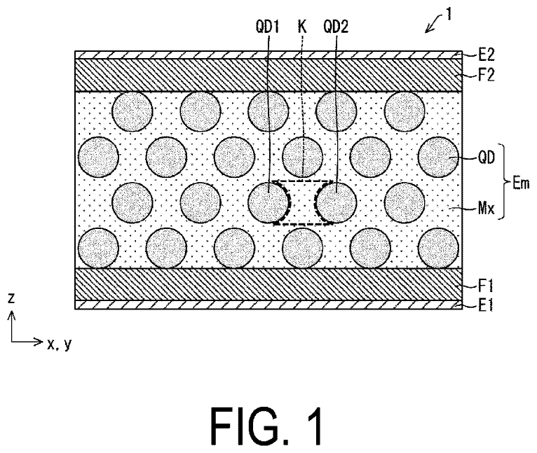

FIG. 1 is a cross-sectional view illustrating an example of a light-emitting element 1 according to a first embodiment of the disclosure. As illustrated in FIG. 1, the light-emitting element 1 includes an anode E1 and a cathode E2 facing each other, and a quantum dot layer Em positioned between the anode E1 and the cathode E2. At least one of the anode E1 or the cathode E2 is a transparent electrode. The quantum dot layer Em is a light-emitting layer. The quantum dot layer Em includes a plurality of quantum dots QD including a first quantum dot QD1 and a second quantum dot QD2, and an inorganic matrix material Mx filling a space between the first quantum dot QD1 and the second quantum dot QD2. The quantum dot layer Em includes a crystalline body serving as a core of the first quantum dot QD1 and an inorganic amorphous material formed at at least a part of a surface of the crystalline body.

The light-emitting element 1 may further include a charge function layer F1 between the anode E1 and the quantum dot layer Em, and/or may further include a charge function layer F2 between the cathode E2 and the quantum dot layer Em. The charge function layers F1 and F2 may include, for example, one or more among a hole injection layer, a hole transport layer, an electron blocking layer, a hole blocking layer, an electron transport layer, and an electron injection layer. The light-emitting element 1 may be a tandem type including a plurality of quantum dot layers Em and a carrier generation layer.

A layer thickness of the quantum dot layer Em may be from 10 to 50 [nm]. A quantum dot density in the quantum dot layer Em may be from 1×10¹⁷ to 6×10¹⁷ [cm³]. An average particle diameter of the plurality of quantum dots QD may be from 5 to 50 [nm].

### Quantum Dot

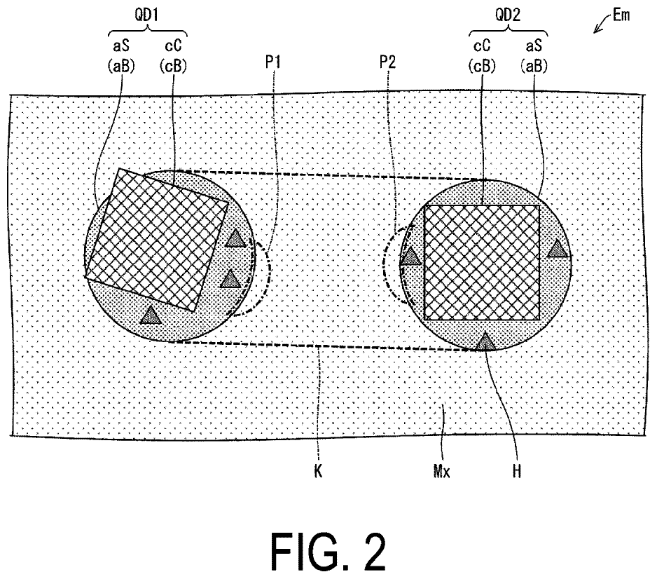

FIG. 2 is a cross-sectional view illustrating an example of the quantum dot layer illustrated in FIG. 1. As illustrated in FIG. 2, each of the first quantum dot QD1 and the second quantum dot QD2 according to the first embodiment has a core-shell structure including a core cC that is crystalline and a shell aS that is amorphous. The shell aS that is amorphous may be provided on a surface of the core cC. The shell aS that is amorphous may be partially formed at the surface of the core cC like the first quantum dot QD1 or may completely cover the core cC like the second quantum dot QD2. The shell aS may be formed at a portion of the surface of the core cC of the first quantum dot QD1, and in this case, the portion faces the second quantum dot QD2. In other words, the shell aS may be formed at at least a part of the surface of the core cC of the first quantum dot QD1 in a region between the core cC of the first quantum dot QD1 and the core cC of the second quantum dot QD2. The shell aS may be made of the same material as the inorganic matrix material Mx or may be made of a different material. The shell aS may be constituted by a plurality of layers, that is, the quantum dot QD may have a multi-shell structure. The inorganic amorphous material aB described above or a part thereof is a shell aS.

In the disclosure, “the same material” and terms similar to “the same material” (for example, “the same substance” and the like) mean materials having the same constituent atom and the same composition ratio thereof. In addition, “a different material” and terms similar to “a different material” (for example, “a different substance” and the like) mean materials having different constituent atoms or materials having the same constituent atom but different composition ratios.

Note that none of FIG. 1, FIG. 2 and the following figures limit the shapes and sizes of the quantum dot QD, the core cC that is crystalline, and the shell aS that is amorphous. None of the figures limit the relationship between the core cC and the shell aS. None of the figures limit the crystal form of the core cC.

The shell aS that is amorphous may contain a halogen H. The shell aS contains, as the halogen H, one or more among fluorine (F), chlorine (CI), bromine (Br), and iodine (I). The halogen H may capture an unpaired electron in the shell aS. The constituent atom of the shell aS is lost at random, resulting in a defect in the shell aS. For example, when the shell aS contains group II-VI compounds, most of the deficiencies are deficiencies of group VI atoms, generating unpaired electrons. The halogen H captures an unpaired electron to close the shell at a site where the deficiency has occurred, leading to stabilization. As a result, the defect is stabilized, the carrier injection efficiency into the quantum dot QD is improved, and EQE of the light-emitting element 1 is improved.

### Matrix Material

The inorganic matrix material Mx is in contact with the quantum dot QD, and is in contact with the shell aS on an outer side of the shell aS. An inner side of the shell aS is in contact with the core cC, and the outer side of the shell aS is opposite to the inner side. The inorganic matrix material Mx according to the present embodiment may include an amorphous portion or does not need to include an amorphous portion. When the inorganic matrix material Mx includes an amorphous portion, the amorphous portion may be in contact with the shell aS. The inorganic matrix material Mx may be made of a different material from or the same material as that of the shell aS. The inorganic amorphous material aB may include both the shell aS and the amorphous portion of the inorganic matrix material Mx.

Referring to FIG. 2 again, the inorganic matrix material Mx includes a portion being in contact with the first quantum dot QD1 and a portion being in contact with the second quantum dot QD2. At least a part of the portion of the inorganic matrix material Mx in contact with the first quantum dot QD1, for example, a portion P1, may be amorphous. At least a part of the portion of the inorganic matrix material Mx in contact with the second quantum dot QD2, for example, a portion P2, may be amorphous. The inorganic matrix material Mx may be amorphous in a region K.

The inorganic matrix material Mx may be mostly or entirely amorphous. For example, in cross-sectional observation, the amorphous portion of the inorganic matrix material Mx may occupy 50% or more, or 70% or more of the entire cross-sectional area of the inorganic matrix material Mx. Moreover, most or all of a portion of the inorganic matrix material Mx in contact with the quantum dot QD may be amorphous. For example, in the cross-sectional observation, a length of the amorphous portion of the inorganic matrix material Mx in contact with the quantum dot QD may account for 50% or more, or 88% or more of an outer peripheral length of the quantum dot. For example, in the cross-sectional observation, the entire portion where the inorganic matrix material Mx is in contact with the first quantum dot QD1 may be amorphous, and the entire portion where the inorganic matrix material Mx is in contact with the second quantum dot QD2 may be amorphous. In particular, it is preferable that the portions of the inorganic matrix material Mx in contact with the quantum dots QD be entirely amorphous.

The inorganic matrix material Mx may include the amorphous portion such that the inorganic amorphous material aB fills the space between the core cC of the first quantum dot QD1 and the core cC of the second quantum dot QD2.

The inorganic matrix material Mx means a member that includes and holds other objects, and can be referred to as a base material, a matrix, or a filler. The inorganic matrix material Mx may be solid at room temperature. The inorganic matrix material Mx may be a member that includes and holds the plurality of quantum dots QD. The inorganic matrix material Mx may be a constituent component of the quantum dot layer Em including the plurality of quantum dots QD.

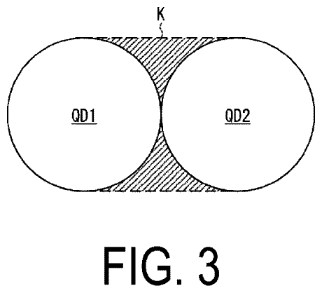

FIG. 3 is a schematic view illustrating an example of the region between the quantum dots illustrated in FIG. 1. The inorganic matrix material Mx may be filled in the quantum dot layer Em. As illustrated in FIG. 1 to FIG. 3, the inorganic matrix material Mx may fill the region (space) K between the first and second quantum dots QD1 and QD2. As illustrated in FIG. 1 and FIG. 3, the region K is a region surrounded by two straight lines (external common tangents) circumscribing the outer peripheries of the first and second quantum dots QD1 and QD2 and the outer peripheries of the first and second quantum dots QD1 and QD2 facing each other in a cross-sectional view. As illustrated in FIG. 3, even when the first quantum dot QD1 is close to the second quantum dot QD2, the region K can exist.

The fact that the inorganic matrix material Mx fills the spaces between the plurality of quantum dots QD means that the inorganic matrix material Mx fills the region K between two quantum dots QD adjacent to each other as described above, and it is sufficient to confirm the fact. In other words, as long as the inorganic matrix material Mx at least fills the region K between the two adjacent quantum dots QD, a desired effect of the inorganic matrix material Mx can be achieved. Thus, the fact that the inorganic matrix material Mx fills the spaces between the plurality of quantum dots QD does not necessarily mean that it is confirmed that the inorganic matrix material Mx fills the spaces between all (more than two) quantum dots QD in a certain range.

As illustrated in FIG. 1, the inorganic matrix material Mx may fill a region (space) other than the plurality of quantum dots QD including the first and second quantum dots QD1 and QD2 in the quantum dot layer Em. The inorganic matrix material Mx may fill a region (space) other than a quantum dot group in the quantum dot layer Em. Note that three or more quantum dots QD including the first and second quantum dots QD1 and QD2 are collectively referred to as the quantum dot group.

Outer edges (an upper surface and a lower surface) of the quantum dot layer Em may be covered with the inorganic matrix material Mx. Alternatively, a portion of the inorganic matrix material Mx may be configured to exist from the outer edges of the quantum dot layer Em, positioning the quantum dot group away from the outer edges. The outer edges of the quantum dot layer Em need not be formed only by the inorganic matrix material Mx, and one or some among the quantum dot group may be exposed from the inorganic matrix material Mx. The inorganic matrix material Mx may indicate a portion of the quantum dot layer Em excluding the quantum dot group.

The inorganic matrix material Mx may enclose the first and second quantum dots QD1 and QD2. The inorganic matrix material Mx may enclose a quantum dot group including the first and second quantum dots QD1 and QD2. The inorganic matrix material Mx may be formed so as to partially or completely fill the space K formed between the first and second quantum dots QD1 and QD2. A void may be present in the quantum dot layer Em. The quantum dot layer Em may include the quantum dot group including the first and second quantum dots QD1 and QD2, and the inorganic matrix material Mx partially or completely may fill a region other than the quantum dot group. The first and second quantum dots QD1 and QD2 may be embedded in the inorganic matrix material Mx at an interval.

The inorganic matrix material Mx may include a continuous film having an area equal to or larger than 1000 nm² along a plane direction orthogonal to a layer thickness direction of the quantum dot layer Em. The continuous film means a film not partitioned by a material other than a material constituting the continuous film in one plane. The continuous film may be in the form of an integrated film connected without interruption by chemical bonding of the material constituting the inorganic matrix material Mx.

The inorganic matrix material Mx may be the same material as the material of the shells of the quantum dot group including the first and second quantum dots QD1 and QD2. In this case, an average distance between the cores adjacent to each other (core-to-core distance) may be equal to or larger than 3 nm or may be equal to or larger than 5 nm. Alternatively, the average distance between the cores adjacent to each other may be 0.5 times or more the average core diameter. The core-to-core distance is an average of distances between adjacent cores in a space including 20 cores. The core-to-core distance may be kept wider than the distance when the shells are in contact with each other. The average core diameter is obtained by averaging the core diameters of the 20 cores in cross-sectional observation in the space including the 20 cores. The core diameter can be the diameter of a circle having the same area as the core area in the cross-sectional observation.

A concentration of the inorganic matrix material Mx in the quantum dot layer Em is, for example, an area percentage occupied by the inorganic matrix material Mx in a cross section of the quantum dot layer Em. This concentration may be 10% or more and 90% or less, or 30% or more and 70% or less in the cross-sectional observation. The concentration may be measured, for example, from an area percentage in image processing in the cross-sectional observation. When the quantum dot group has a core-shell structure, the concentration of the shells may be 1% or more and 50% or less. When the shells and the inorganic matrix material Mx are constituted by the same material (same composition) and the shells and the inorganic matrix material Mx cannot be distinguished from each other, the concentration of the region including the shells and the inorganic matrix material Mx may be within a numerical range obtained by adding the numerical range of the concentration of the shells to the numerical range of the concentration of the inorganic matrix material Mx. The percentages of the cores and the shells of the quantum dot group, and the inorganic matrix material Mx may be adjusted, as appropriate, such that the total thereof is 100% or less.

As described above, when the shell and the inorganic matrix material Mx cannot be distinguished from each other, the shell may be regarded as the amorphous portion of the inorganic matrix material Mx, and the inorganic amorphous material aB may include the shell. In other words, in the above case, regardless of the structure of the quantum dot QD used at the time of manufacturing, based on observation after the manufacturing, the quantum dot QD may be regarded as a shell-less type constituted by a core, the inorganic matrix material Mx may be regarded as being in direct contact with the quantum dot QD, and the quantum dot layer Em may be regarded as including the quantum dot QD and the inorganic matrix material Mx. Then, the inorganic amorphous material aB includes the amorphous portion of the inorganic matrix material Mx, and the amorphous portion may include a portion that has been the shell of the quantum dot QD at the time of the manufacturing.

The quantum dot layer Em may be constituted by the quantum dot group including the first and second quantum dots QD1 and QD2, and the inorganic matrix material Mx.

Regarding the structure of the inorganic matrix material Mx, the configuration described above need not be observed over the entirety of the quantum dot layer Em as long as the configuration described above is understood by observing the quantum dot layer Em across a width of about 100 nm in the cross-sectional observation unless otherwise noted or unless a contradiction arises. The inorganic matrix material Mx may contain a substance different from the main material (for example, an inorganic substance such as an inorganic semiconductor), for example, as an additive. The observation result of a portion of the quantum dot layer Em may be applied to the entire quantum dot layer Em.

### Electron Beam Diffraction Image

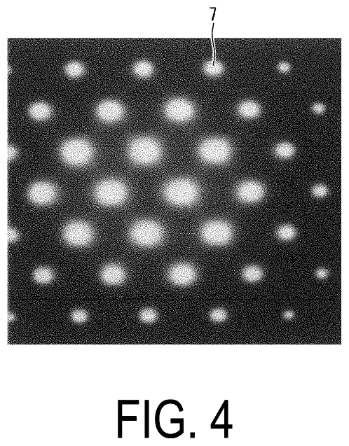

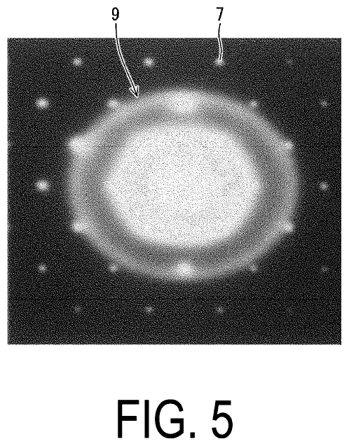

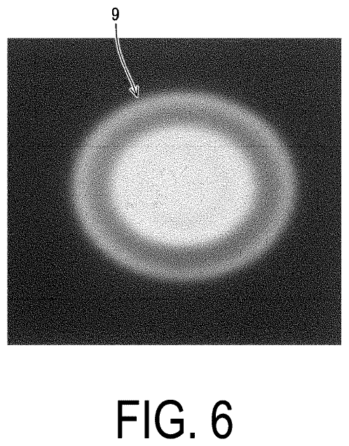

Each of FIG. 4 to FIG. 6 is a view illustrating an example of an electron beam diffraction image obtained from a sample in which the crystalline portion and the amorphous portion are mixed in the continuous film. FIG. 4 illustrates an electron beam diffraction image obtained by electron beam diffraction at the crystalline portion of the sample and includes a bright spot group pattern. FIG. 5 illustrates an electron beam diffraction image obtained by electron beam diffraction at a boundary portion between the crystalline portion and the amorphous portion of the sample, and includes the bright spot group pattern and a halo pattern 9 in an overlapping manner. FIG. 6 illustrates an electron beam diffraction image obtained by electron beam diffraction at the amorphous portion of the sample, and includes the halo pattern 9. The bright spot group pattern includes a plurality of bright spots 7 regularly arrayed, and the halo pattern 9 includes a concentric bright-dark pattern. Note that in FIG. 4 and FIG. 5, as the bright spot group pattern of the electron beam diffraction image obtained by electron beam diffraction at the crystalline portion, a six fold rotational symmetry pattern caused by a hexagonal crystal is illustrated, but an electron beam diffraction image to be obtained is not limited thereto. In FIG. 5 and FIG. 6, the concentric bright-dark pattern in which a bright portion and a dark portion are repeated is illustrated as the halo pattern 9, but the halo pattern 9 is not limited thereto. Additionally, the boundary portion between the crystalline portion and the amorphous portion includes a boundary between the crystalline portion and the amorphous portion and the vicinity of the boundary.

Note that in this specification, an electron beam diffraction image of a certain portion is obtained by electron beam irradiation with a field of view limited only to the portion. To be specific, in this specification, the electron beam diffraction image of the portion is obtained by limiting an irradiation field so as to irradiate only the portion with the electron beam, limiting a detection field so as to detect only the electron beam having passed through the portion, or limiting both the irradiation field and the detection field.

Thus, the electron beam diffraction image including the halo pattern 9 is obtained by irradiating the inorganic amorphous material aB with the electron beam. That is, the electron beam diffraction image including the halo pattern 9 is obtained by irradiating the shell aS with the electron beam. When the inorganic matrix material Mx includes the amorphous portion, an electron beam diffraction image including the halo pattern 9 is obtained by irradiating the amorphous portion with an electron beam. By irradiating the crystalline body cB with an electron beam, that is, by irradiating the core cC with an electron beam, an electron beam diffraction image including a bright spot group pattern is obtained. By irradiating the boundary portion between the core cC and the shell aS with an electron beam, an electron beam diffraction image including the bright spot group pattern and the halo pattern 9 superimposed on each other is obtained. By irradiating the boundary portion between the core cC and the amorphous portion of the inorganic matrix material Mx with an electron beam, an electron beam diffraction image including the bright spot group pattern and the halo pattern 9 superimposed on each other is obtained.

The inorganic matrix material Mx may include a portion that is monocrystalline or polycrystalline. Thus, an electron beam diffraction image of any part of the inorganic matrix material Mx may include a bright spot group pattern. Alternatively, the entire inorganic matrix material Mx may be amorphous.

Note that whether the target portion is crystalline or amorphous may be determined by using a visual resource other than the electron beam diffraction image. For example, whether an atomic arrangement is periodic or irregular may be determined from a photograph taken by using a high-resolution Transmission Electron Microscope (TEM). In the photograph, a portion representing a periodic atomic arrangement is crystalline, and a portion representing an irregular atomic arrangement is amorphous.

### Material

The core cC may contain a group III-V compound, and the inorganic amorphous material aB may contain a group II-VI compound. The materials of the core cC and the inorganic amorphous material aB may be selected such that the band gap of the inorganic amorphous material aB is larger than the band gap of the core cC. For example, the core cC of the quantum dot QD1 may contain indium phosphide (InP), and the inorganic amorphous material aB may contain zinc sulfide (ZnS). For example, the core cC of the quantum dot QD1 may contain indium phosphide (InP), and the inorganic amorphous material aB may contain a mixed crystal of zinc sulfide (ZnS) and at least one of magnesium sulfide (MgS) and lithium sulfide (Li₂S). The “mixed crystal” that is amorphous means an amorphous material constituted by two or more atoms in the same group, or an amorphous material constituted by three or more atoms, all of which belong to different groups or at least two of which are in the same group.

In the disclosure, the numbering of groups of atoms by using Roman numerals is numbering based on the old International Union of Pure and Applied Chemistry (IUPAC) system, and the numbering of groups of atoms by using Arabic numerals is numbering based on the new IUPAC system. Note that the group II-VI compound refers to a compound constituted by a group II atom and a group VI atom, and the group III-V compound refers to a compound constituted by a group III atom and a group V atom.

Composition percentages of the materials constituting the quantum dot QD and the inorganic matrix material Mx may be different from the stoichiometric composition (stoichiometry).

When the shell aS and the inorganic matrix material Mx are made of different materials, the materials of the core cC, the shell aS, and the inorganic matrix material Mx may be selected such that a band gap of the shell aS is equal to or larger than a band gap of the core cC, and a band gap of the inorganic matrix material Mx is equal to or larger than the band gap of the shell aS. For example, the shell aS contains a group II-VI compound, the inorganic matrix material Mx contains a group II-VI compound, and at least one of the group II atom and the group VI atom contained in the shell aS belongs to an upper period in the periodic table than that of at least one of the group II atom and the group VI atom contained in the inorganic matrix material Mx. For example, the core cC contains indium phosphide (InP), the shell aS contains zinc sulfide (ZnS), and the inorganic matrix material Mx contains a mixed crystal of zinc sulfide (ZnS) and at least one of magnesium sulfide (MgS) and lithium sulfide (Li₂S).

When the mixed crystal is used for the shell aS and/or the inorganic matrix material Mx, composition percentages of the mixed crystal may be within a range that can be achieved as a solid phase composition. For example, the upper limit of an amount of magnesium and lithium that can be substituted for zinc is about 20% in terms of substance amount percentage relative to that of zinc in zinc sulfide before substitution while a hexagonal crystal structure of zinc sulfide (ZnS) is being maintained. The upper limit of an amount of the material containing magnesium and the material containing lithium in the formation of the mixed crystal is about 30% in terms of mass percentage relative to that of the material containing zinc. Since magnesium sulfide and lithium sulfide are cubic crystals, when the magnesium material and the lithium material are mixed in an amount exceeding the upper limit, magnesium and lithium are not incorporated as a solid phase composition of zinc sulfide, but are mixed as impurities or phases having different crystal systems. Thus, when the composition percentages of the mixed crystal are outside the range that can be achieved as the solid phase composition, it is difficult to make the mixed crystal uniformly amorphous. On the other hand, when the composition percentages are within the range, it is easy to make the mixed crystal uniformly amorphous. The uniform amorphous body is useful for improving characteristics of the shell aS and/or the inorganic matrix material Mx, and is useful for improving EQE of the light-emitting element 1. A halogen H may be added to the mixed crystal.

When the shell aS and the inorganic matrix material Mx contain different materials, the shell aS and the inorganic matrix material Mx can be distinguished from each other by composition analysis. A composition of the portions included in the quantum dot layer can be analyzed by using any one of Secondary Ion Mass Spectrometry (SIMS), Auger Electron Spectroscopy (AES), Gas Chromatograph Mass Spectrometry (GCMS), X-ray Photoelectron Spectroscopy (XPS), and Energy Dispersive X-ray spectroscopy (EDX), or by using any two or more thereamong in combination.

### Light-Emitting Element Manufacturing Method

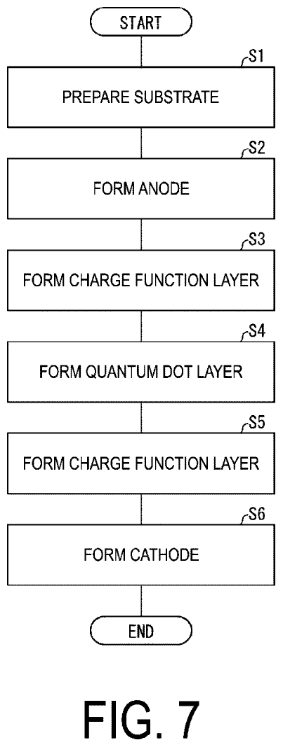

FIG. 7 is a flowchart illustrating an example of a light-emitting element manufacturing method illustrated in FIG. 1. As illustrated in FIG. 7, the light-emitting element manufacturing method may sequentially include preparing a substrate (step S1), forming an anode E1 on the substrate (step S2), forming a charge function layer F1 on the anode E1 (step S3), forming a quantum dot layer Em on the charge function layer F1 (step S4), forming a charge function layer F2 on the quantum dot layer Em (step S5), and forming a cathode E2 on the charge function layer F2 (step S6).

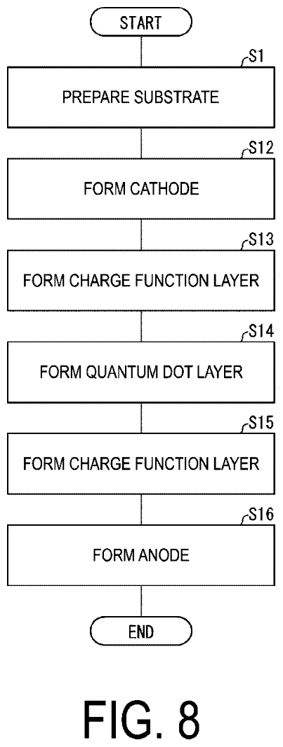

FIG. 8 is a flowchart illustrating another example of the manufacturing method for the light-emitting element illustrated in FIG. 1. As illustrated in FIG. 8, the light-emitting element manufacturing method may sequentially include preparing a substrate (step S1), forming a cathode E2 on the substrate (step S12), forming a charge function layer F2 on the cathode E2 (step S13), forming a quantum dot layer Em on the charge function layer F2 (step S14), forming a charge function layer F1 on the quantum dot layer Em (step S15), and forming an anode E1 on the charge function layer F1 (step S16).

### Manufacturing Method for Quantum Dot Layer

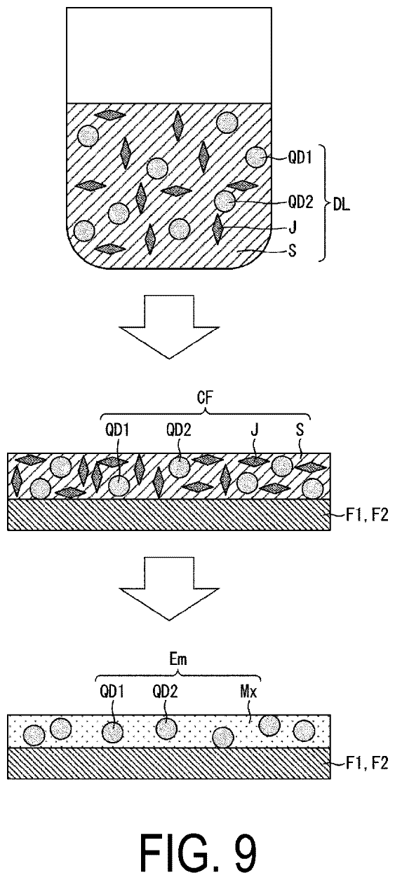

FIG. 9 is a diagram illustrating an example of a case where the inorganic matrix material Mx contains a group II-VI compound in the forming of the quantum dot layer illustrated in FIG. 1. First, a plurality of quantum dots QD including the first quantum dot QD1 and the second quantum dot QD2 are synthesized. The method for synthesizing the quantum dots QD will be described later. Next, as illustrated in the upper part of FIG. 9, the quantum dots and a precursor J of the group II-VI compound are dispersed in a solvent S to obtain a quantum dot dispersion DL. The quantum dot dispersion DL includes the first quantum dot QD1, the second quantum dot QD2, the precursor J, and the solvent S.

Next, as illustrated in the middle part of FIG. 9, the quantum dot dispersion DL is applied on the charge function layer F1 or the charge function layer F2 to form a coating film CF. The coating film CF includes the first quantum dot QD1, the second quantum dot QD2, the precursor J, and the solvent S.

Next, as illustrated in the lower part of FIG. 9, the coating film CF is heated and cooled to form the quantum dot layer Em. In this step, first, the coating film CF is heated so as to remove the solvent S from the coating film CF. Subsequently or simultaneously, the coating film CF is heated such that the precursor J in the coating film CF is modified into a group II-VI compound. Then, the coating film CF is rapidly cooled, for example, at a rate of 100 degrees Celsius/second or more. This rapid cooling solidifies the group II-VI compound faster than an average time required for the constituent atoms of the group II-VI compound to move to intrinsic crystal lattice points of the group II-VI compound. Thus, most or all of the constituent atoms are not positioned at the unique crystal lattice points. That is, the group II-VI compound becomes amorphous, and the inorganic matrix material Mx that is amorphous is formed. In addition, the coating film CF may be cooled to a sufficiently low temperature, for example, 40 degrees Celsius or less so that the constituent atoms do not obtain thermal energy necessary for the constituent atoms to move to the crystal lattice points after the cooling. The sufficient cooling maintains the disordered amorphous state without transitioning to an ordered crystalline state. During and/or after the heating, a heat retention period in which the temperature of the coating film CF is maintained may be provided for the purpose of securing a reaction time for the modification of the precursor J or the like.

The manufacturing method for the quantum dot layer Em according to the disclosure is not limited to the above-described method. The inorganic matrix material Mx may contain a material or impurities other than the group II-VI compound, and the inorganic matrix material Mx may be amorphized by a method other than the rapid cooling.

In addition to the rapid cooling, for example, the maximum heating temperature of the coating film CF may be made lower than that when the inorganic matrix material is crystallized. By low-temperature heating, the constituent atoms cannot obtain sufficient thermal energy to move to the crystal lattice points. When the inorganic matrix material contains the group II-VI compound, the precursor J can be modified in the entire coating film CF and the inorganic matrix material Mx can be substantially uniformly amorphized by lowering the maximum heating temperature by about 50 degrees Celsius and prolonging the reaction time by about 50% as compared with the case of crystallization.

### Quantum Dot Manufacturing Method

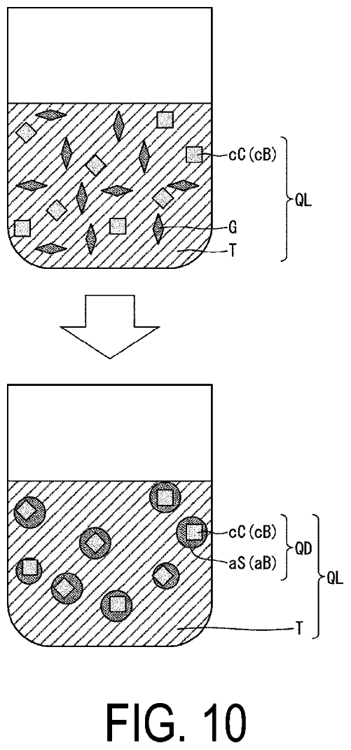

FIG. 10 is a diagram illustrating an example in which the core cC contains a group III-V compound and the shell aS contains a group II-VI compound in the forming of the quantum dots illustrated in FIG. 1. First, in Comparative Example 1, a crystalline body cB of the group III-V compound is synthesized as the core cC. The crystalline body cB may be synthesized by any method, and a known method may be used. Next, as illustrated in the upper part of FIG. 10, the core cC that is crystalline and a precursor G of the group II-VI compound are dispersed in a solvent T to synthesize a solution QL. The solution QL includes the core cC that is crystalline, the precursor G of the group II-VI compound, and the solvent T.

Next, as illustrated in the lower part of FIG. 10, the solution QL is heated and cooled to synthesize the quantum dots QD. In this step, first, the solution QL is heated so that the precursor G in the solution QL is modified into the group II-VI compound. Then, the solution QL is rapidly and primarily cooled, for example, at a rate of 100 degrees Celsius/second or more. This rapid cooling solidifies the group II-VI compound faster than the average time required for the constituent atoms of the group II-VI compound to move to the intrinsic crystal lattice points of the group II-VI compound. Thus, the group II-VI compound becomes amorphous, and the shell aS that is amorphous is formed. In addition, the solution QL may be cooled to a sufficiently low temperature, for example, 25 degrees Celsius or less such that the constituent atoms do not obtain thermal energy necessary for the constituent atoms to move to the crystal lattice points after the cooling. The sufficient cooling maintains the disordered amorphous state without transitioning to an ordered crystalline state. During and/or after the heating, a heat retention period in which the temperature of the solution QL is maintained may be provided for the purpose of ensuring a reaction time for modification of the precursor G or the like.

In synthesizing the quantum dots QD, the temperature of the primarily cooled solution QL may be maintained for a certain period of time. By maintaining this temperature, a reduction in point defects in the shell aS can be expected. After maintaining the temperature, the solution QL may be secondarily cooled. A rate of the secondary cooling may be slower than the primary cooling. The gradual cooling can be expected to reduce defects exposed at the surface.

As described above, the quantum dot QD including the core cC that is a semiconductor crystal and the shell aS that is an inorganic amorphous material is synthesized. The maximum diameter of the quantum dot QD is equal to or less than 100 [nm]. The method for synthesizing the quantum dots QD according to the disclosure is not limited to the method described above, and the core cC may contain an inorganic semiconductor material other than the group III-V compound. The shell aS may contain a material or impurities other than the group II-VI compound. In the synthesizing of the quantum dots QD, the shell aS may be amorphized by a method other than the rapid cooling.

In the synthesizing of the quantum dots QD, a material containing the halogen H may be added to the solution QL so that the shell aS contains the halogen H. When the halogen His fluorine (F), the material containing the halogen H may be, for example, fluoromethane, trifluoroacetic acid, or the like. When the halogen H is an atom other than fluorine, the fluorine in the above material may be substituted. Further, the precursor G may contain a material containing the halogen H so that the shell aS contains the halogen H. For example, trifluoroacetic acid may be used as the precursor G.

### Miller Plane Indices

In this specification, Miller plane indices are used to represent crystal planes. That is, for crystals other than a hexagonal crystal, given unit lattice vectors a₁, a₂, and a₃ and integers h, k, and 1, a crystal plane passing through three points specified by 1/h*vector a₁, 1/k*vector a₂, and 1/1*vector a₃ is referred to as an (hkl) plane. Further, for a hexagonal crystal, given further a unit lattice vector as defined by a₄:=−a₁−a₂ and an integer i defined by i:=−h−k, a crystal plane passing through the three points described above is referred to as an (hkil) plane.

In this specification, for a crystal other than a hexagonal crystal, the (hkl) plane and planes equivalent to the (hkl) plane are collectively referred to as (hkl) equivalent planes. Further, for a hexagonal crystal, the (hkil) plane and planes equivalent to the (hkil) plane are collectively referred to as (hkil) equivalent planes.

### Comparison with Comparative Example 1

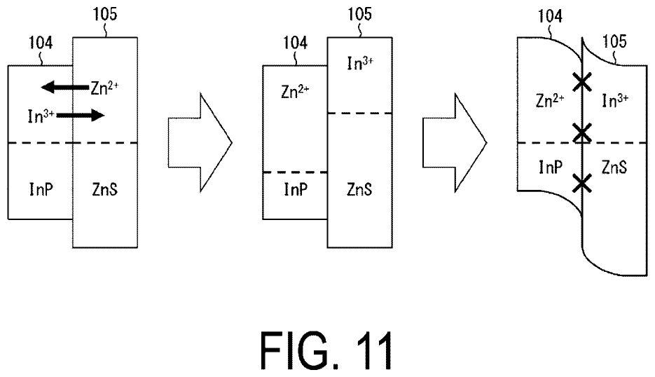

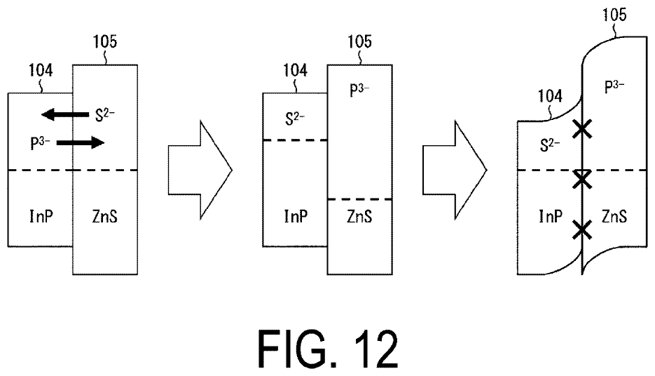

Each of FIG. 11 and FIG. 12 is a diagram illustrating an example of a band structure of the quantum dots of Comparative Example 1. Rectangles and deformed rectangles in the figure indicate band gaps, a lower base of the rectangle indicates a Highest Occupied Molecular Orbital (HOMO), and an upper base of the rectangle indicates a Lowest Unoccupied Molecular Orbital (LUMO). A broken line in the figure indicates a Fermi level. In the figure, “x” indicates a defect level. A quantum dot 103 of Comparative Example 1 has a core-shell structure including a core 104 that is crystalline and a shell 105 that is crystalline. The core 104 contains zinc blende indium phosphide (InP) and the shell 105 contains wurtzite zinc sulfide (ZnS).

In manufacturing of the quantum dot 103, in particular, at the initial stage of formation of the shell 105, constituent atoms mutually diffuse between the core 104 and the shell 105. The diffusion of atoms having different valences from each other causes so-called “auto-doping” in the quantum dot 103. Specifically, the following five processes (a) to (e) are assumed to occur.
(a) As illustrated in FIG. 11, zinc (Zn), which is a group II atom, diffuses from the shell 105 to the core 104 and substitutes for indium (In), which is a group III atom. This substitution allows the core 104 to be doped into a p-type.
(b) As illustrated in FIG. 11, indium diffuses from the core 104 into the shell 105 and substitutes for zinc, which is a group II atom. This substitution causes the shell 105 to be doped into an n-type.
(c) As illustrated in FIG. 12, sulfur(S), which is a group VI atom, diffuses from the shell 105 to the core 104 and substitutes for phosphorus (P), which is a group V atom. This substitution allows the core 104 to be doped into an n-type.
(d) As illustrated in FIG. 12, sulfur diffuses from the core 104 into the shell 105 and substitutes for phosphorus. This substitution allows the shell 105 to be doped into a p-type.
(e) No substitution occurs at sites. Specifically, one site loses an atom and then does not gain another atom. The vacant site causes a deep defect level at an interface between the core 104 and the shell 105, as illustrated in FIG. 11 and FIG. 12.

Thus, a pn junction is formed between the core 104 and the shell 105. Depending on a direction of the pn junction, the confinement of either electrons or holes injected into the core 104 is reduced and the probability of radiative recombination in the core 104 is reduced. The defect level further reduces the probability of radiative recombination in the core 104.

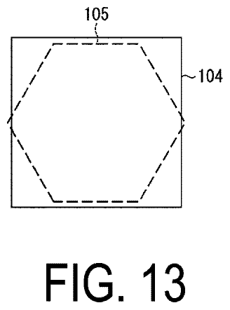

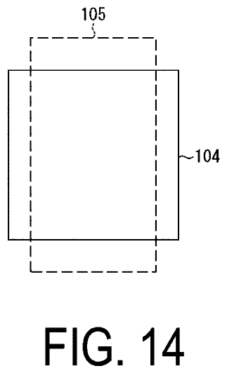

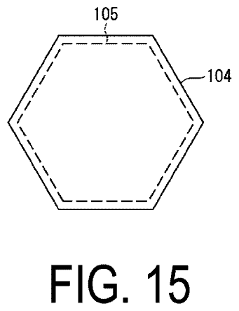

Each of FIG. 13, FIG. 14, and FIG. 15 is a diagram illustrating a crystal system in the quantum dot of Comparative Example 1. The solid line in the figure indicates a unit lattice of the core 104, and the broken line in the figure indicates a unit lattice of the shell 105. As illustrated in FIG. 13, FIG. 14, and FIG. 15, a crystal plane and a lattice shape at the interface between the core 104 and the shell 105 can be combined in three ways.

As a general tendency, the ionicity of group II-VI compounds is stronger than that of group III-V compounds. Ionic compounds tend to exhibit crystal systems in the order of a zinc blende type (cubic crystal, 4-coordination), a wurtzite type (hexagonal crystal, 4-coordination), and a rock salt type (cubic crystal, 6-coordination) from a compound having a weak ionicity to a compound having a strong ionicity. The stronger the bond between constituent atoms, that is, the stronger the ionicity of an ionic compound, the smaller the inter-atom distance and the lattice constant.

As illustrated in FIG. 13, when a (0001) equivalent plane of the shell 105 is combined with a (001) equivalent plane or a (011) equivalent plane of the core 104, shapes of the crystal lattices of the core 104 and the shell 105 are different from each other. Further, as illustrated in FIG. 14, when a (10-10) equivalent plane or a (11-20) equivalent plane of the shell 105 is combined with the (001) equivalent plane of the core 104, shapes of the crystal lattices of the core 104 and the shell 105 are different from each other. Thus, the interface between the core 104 and the shell 105 is a discontinuous boundary surface at which crystals are in contact with each other such that at least one of crystal orientations and the crystal lattices do not match each other. At the interface, the crystal lattices are disordered and defect levels are generated at a high density.

As illustrated in FIG. 15, when a (111) equivalent plane of the core 104 is combined with the (0001) equivalent plane of the shell 105, the shapes of the crystal lattices are the same regular hexagon. However, since the lattice constant of the core 104 is different from that of the shell 105, the shell 105 is distorted. A lattice constant of zinc blende indium phosphide on the (111) equivalent plane is larger than a lattice constant of wurtzite zinc sulfide on the (0001) equivalent plane. Thus, a mismatch of the crystal lattices occurs at the interface between the core 104 and the shell 105, and as the film thickness of the shell 105 increases, a larger number of cracks are generated at the shell 105.

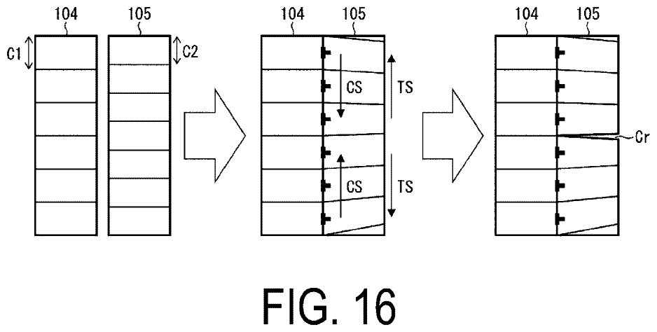

FIG. 16 is a cross-sectional view illustrating a bonding example of a core having a large lattice constant and a shell having a small lattice constant. As illustrated in FIG. 16, when the shapes of the crystal lattices of the core 104 and the shell 105 are the same, the shell 105 is grown on the core 104 such that the crystal lattices match each other at the interface between the core 104 and the shell 105. On the other hand, a lattice constant C1 of the core 104 is different from a lattice constant C2 of the shell 105, and C1>C2 is satisfied. As a result, the shell 105 is distorted, a compressive stress CS is generated on an interface side with the core 104, and a tensile stress TS is generated on a surface side opposite to the core 104. At the interface between the core 104 and the shell 105, a defect indicated by a T-shape occurs. The crack Cr releases distortion energy and relaxes the compressive stress CS and the tensile stress TS.

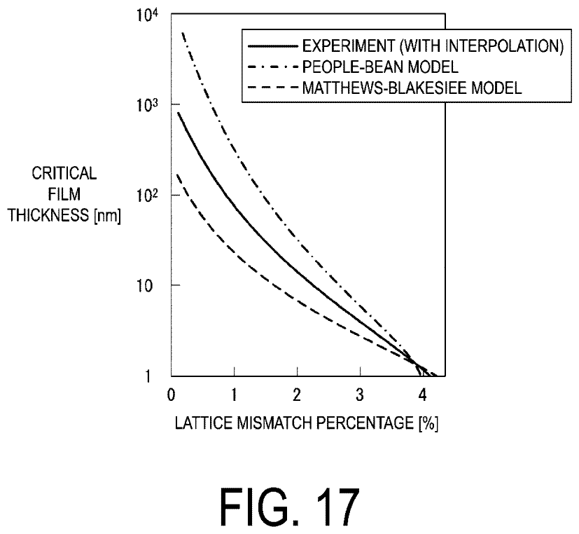

FIG. 17 is a graph illustrating relationships between lattice mismatch percentages [%] and critical film thicknesses [nm]. The lattice mismatch percentage [%] is a value obtained by dividing a difference in lattice constant between an underlayer and a layer grown on the underlayer by a lattice constant of the underlayer. The critical film thickness is a critical value or a maximum value of the film thickness at which no crack Cr is expected to occur at the layer grown on the underlayer. The solid line in the figure includes interpolation based on experimental results. The broken line in the figure is based on the Matthews-Blakesiee model. The dashed-dotted line in the figure is based on the People-Bean model. As illustrated in FIG. 17, the crack Cr occurs at the layer grown on the underlayer when the lattice mismatch percentage is equal to or more than 2% and the film thickness is equal to or more than 10 nm.

Due to the above, the quantum dot 103 of Comparative Example 1 has a short light emission lifetime and a low radiative recombination probability.

According to the manufacturing method of the disclosure, by the rapid cooling of the solution QL, almost no movement time is given to the constituent atoms. Thus, diffusion and auto-doping of the constituent atoms are reduced. Furthermore, the quantum dot QD according to the disclosure includes the shell aS that is amorphous, and the interface between the core cC and the shell aS is not a discontinuous boundary surface where crystals are in contact with each other such that at least either the crystal orientations or the crystal lattices do not match each other. Thus, the number of defect levels generated at the interface is smaller than that in Comparative Example 1. In addition, the shell aS has no or little distortion caused by the compressive stress CS and the tensile stress TS, and has no or little crack Cr.

Thus, compared to the quantum dot 103 of Comparative Example 1, the quantum dot QD according to the disclosure has a long light emission lifetime and a high radiative recombination probability at the core cC. In addition, the light-emitting element 1 according to the disclosure has a high external quantum efficiency (EQE).

### Comparison with Comparative Example 2

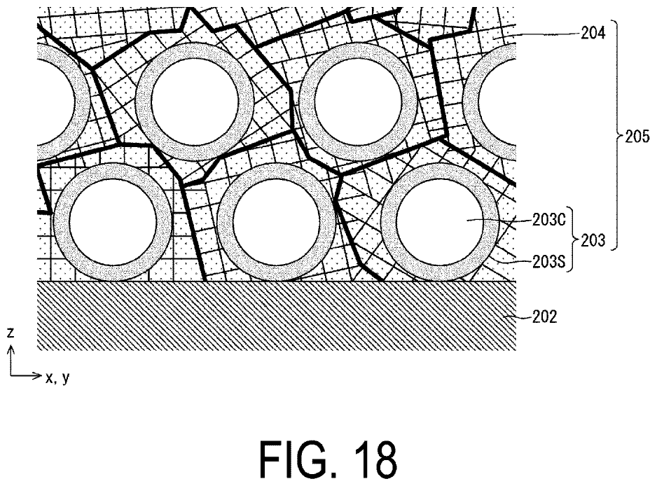

FIG. 18 is a cross-sectional view illustrating a quantum dot layer of Comparative Example 2. As illustrated in FIG. 18, a quantum dot layer 205 is formed by applying a dispersion including quantum dots 203 and a precursor of an inorganic matrix material 204 on an underlayer 202. The quantum dot 203 includes a core 203C that is crystalline and a shell 203S that is crystalline. Since the inorganic matrix material 204 is crystalline and positions and crystal orientations of the quantum dots 203 are random, a discontinuous boundary surface where crystals are in contact with each other is generated such that at least either the crystal orientations or the crystal lattices do not match each other. Such a discontinuous boundary surface is positioned in the inorganic matrix material 204 or at a boundary between the quantum dot 203 and the inorganic matrix material 204. Due to crystal plane mismatch between the core side 203C and the shell side 203S, such a discontinuous boundary surface is positioned particularly near the core 203C. At the discontinuous boundary surface and in the vicinity thereof, dangling bonds are generated at a high density, and the dangling bonds become carrier traps or non-radiative centers, so that the external quantum efficiency (EQE) of the light-emitting element according to Comparative Example 2 is reduced.

Since the shell aS of the quantum dot QD according to the disclosure is amorphous, the boundary between the shell aS of the quantum dot QD and the inorganic matrix material Mx is not a boundary surface where crystals are in contact with each other. Thus, even when the inorganic matrix material Mx according to the disclosure is crystalline similarly to the inorganic matrix material 204 of Comparative Example 2, the quantum dot layer Em according to the disclosure has a small number of discontinuous boundary surfaces at which crystals are in contact with each other such that at least either the crystal orientations or the crystal lattices do not match each other. Thus, compared to the quantum dot layer 205 of Comparative Example 2, the quantum dot layer Em according to the disclosure has fewer dangling bonds, and the EQE of the light-emitting element 1 according to the disclosure is improved. Furthermore, when the inorganic matrix material Mx according to the disclosure includes an amorphous portion, the number of boundary surfaces at which crystals are in contact with each other in the inorganic matrix material Mx is small, and the EQE of the light-emitting element 1 according to the disclosure is further improved. In addition, the inorganic amorphous material aB formed at at least a part of the surface of the crystalline body cB can reduce the number of discontinuous boundary surfaces in the vicinity of the core 203C. Thus, according to the above configuration, the EQE of the light-emitting element 1 according to the disclosure is further improved.

### Example 1

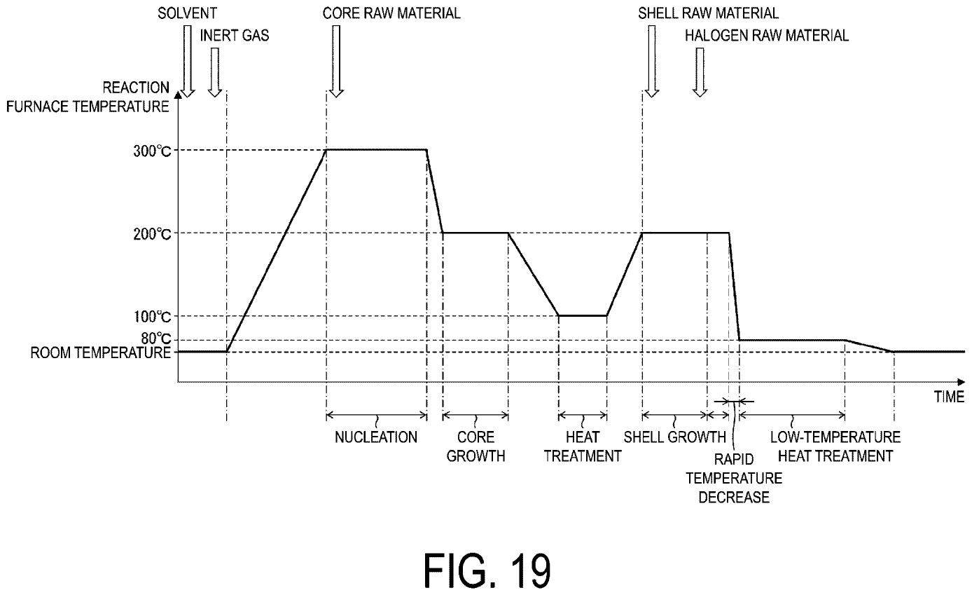

FIG. 19 is a time-series change diagram of the temperature of a reaction furnace used in a quantum dot manufacturing method according to Example 1 of the disclosure. The arrows illustrated in FIG. 19 indicate time points at which a solvent, an inert gas, a core raw material, a shell raw material, and a halogen raw material are charged into the reaction furnace. In the present embodiment, as illustrated in FIG. 19, the temperature of the reaction furnace was raised, lowered, and maintained while the above-described materials were charged into the reaction furnace.

The solvent was a mixture of trioctylphosphine oxide and hexadecylamine at a weight ratio of 2:1. The inert gas was argon (Ar). The core material was triethylindium and powdered phosphorus (P). The shell material was diethylzinc and powdered sulfur (S). The halogen material was fluoromethane or trifluoroacetic acid. Octylamine and bis(trimethylsilyl)sulfide were additives for stabilizing a synthesizing reaction by temporarily modifying a defect at the surface of the core or shell in the synthesizing process.

A total substance amount of triethylindium and diethylzinc is “a-1 [mol]”, a substance amount of a halogen raw material is “a-2 [mol]”, a total substance amount of powdered phosphorus and sulfur is “b [mol]”, a substance amount of octylamine is “c [mol]”, and a substance amount of bis(trimethylsilyl)sulfide is “d [mol]”. A substance amount ratio of the raw materials is a-1:a-2:b:c:d=10:0.01:9:7:3. The substance amount ratio is also referred to as a “mole ratio”.

First, a solvent was charged into a reaction furnace, an inert gas was sealed therein, and a temperature of the reaction furnace was raised to 300 degrees Celsius and maintained. After the solvent was liquefied, a core material, octylamine, and bis(trimethylsilyl)sulfide were injected into the reaction furnace by using a high-pressure injector to decompose the core material and thus to produce seed crystals of the cores cC. Then, the temperature of the reaction furnace was then lowered to 200 degrees Celsius at a rate of 400° C./minute and maintained. The seed crystals were grown at a rate of 10 nm/200 minutes at 200 degrees Celsius.

Subsequently, the temperature of the reaction furnace was decreased to 100 degrees Celsius at a rate of 30 degrees Celsius/second or less and maintained at 100 degrees Celsius for 1 hour. Then, the temperature of the reaction furnace was raised to 200 degrees Celsius, maintained at 200 degrees Celsius for 1 minute after the shell raw material was injected into the reaction furnace, and further maintained at 200 degrees Celsius for 1 minute after the halogen raw material was injected into the reaction furnace. Immediately thereafter, the temperature of the reaction furnace was lowered to 80 degrees Celsius at a rate of 100 degrees Celsius/second (primary cooling). Then, after the temperature of the reaction furnace was maintained at 80 degrees Celsius for 30 minutes, the temperature of the reaction furnace was decreased to a room temperature at a rate of 100 degrees Celsius/second (secondary cooling). The room temperature was 25 degrees Celsius.

As described above, the quantum dot QD including the core cC being crystalline and containing indium phosphide, and the shell aS being amorphous and containing zinc sulfide and chlorine was manufactured. In a typical manufacturing method for a quantum dot having a shell that is crystalline and that contains zinc sulfide, a temperature of a reaction furnace is raised to 250 degrees Celsius or more, a shell material is injected, and the temperature of the reaction furnace is lowered at a rate of 50 degrees Celsius/sec or less. As compared with the typical method, the present example can reduce auto-doping due to two factors, that is, the low temperature in the shell formation, and the rapid cooling rate.

### Example 2 and Example 3

The light-emitting element 1 of Example 2 according to the disclosure was fabricated such that the entire inorganic matrix material Mx was amorphous and the shell aS of the quantum dot QD was amorphous. In addition, the light-emitting element 1 of Example 3 according to the disclosure was fabricated such that the entire inorganic matrix material Mx was crystalline (more specifically, polycrystalline) and the shell aS of the quantum dot QD was amorphous. Furthermore, the light-emitting element including the quantum dot layer 205 of Comparative Example 2 was fabricated such that the entire inorganic matrix material 204 was crystalline (more specifically, polycrystalline) and the shell 203S of the quantum dot 203 was amorphous. In other respects, for example, materials, layer thicknesses, and carrier concentrations were made similar to each other.

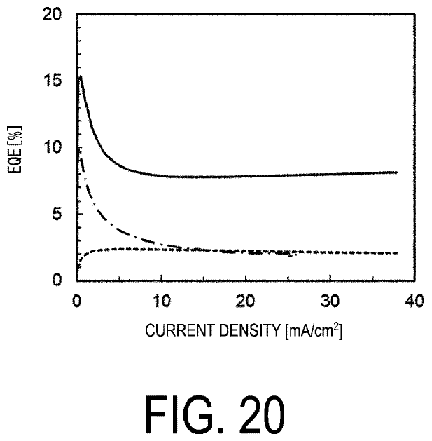

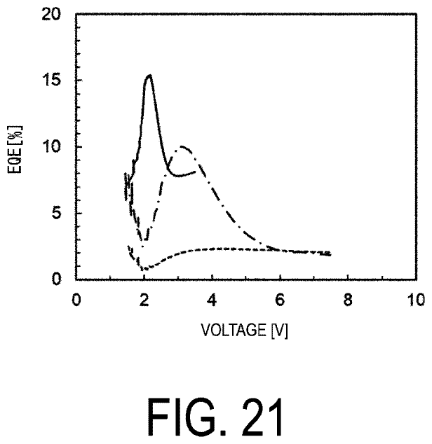

FIG. 20 is a current density-EQE graph of the light-emitting elements of Comparative Example 2, Example 2, and Example 3. FIG. 21 is a voltage-EQE graph of the light-emitting elements of Comparative Example 2, Example 2, and Example 3. In FIG. 20 and FIG. 21, the broken line indicates the characteristics of Comparative Example 2, the solid line indicates the characteristics of Example 2, and the dashed dotted line indicates the characteristics of Example 3. As illustrated in FIG. 20, in comparison of maximum EQE and the current density at which the maximum EQE is exhibited, the maximum EQE of Comparative Example 2 is about 2%, whereas the maximum EQE of Example 3 is about 10% and the maximum EQE of Example 2 is about 15%, resulting in significant improvement. The current density at which the maximum EQE is exhibited is about 7 mA/cm² in Comparative Example 2, whereas the current density is reduced to 1 mA/cm² or less in Example 3 and Example 2, which indicates that defects in the light-emitting layer serving as non-radiative centers are reduced. Further, as illustrated in FIG. 21, the voltage of the maximum EQE is about 4 V in Comparative Example 2, but decreases to about 3 V in Example 3 and to about 2 V in Example 2. It is considered that the defects in the light-emitting layer were reduced, so that carriers were hardly trapped and the voltage required for injection was reduced.

### Second Embodiment

Another embodiment of the disclosure will be described below. Further, members having the same functions as those of the members described in the above-described embodiments will be denoted by the same reference numerals and signs, and the description thereof will not be repeated for the sake of convenience of description.

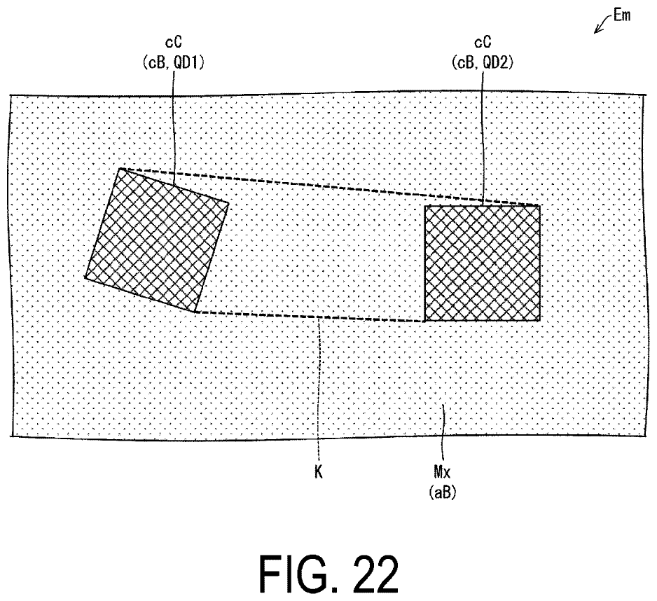

FIG. 22 is a cross-sectional view illustrating an example of a quantum dot layer according to an embodiment of the disclosure. As illustrated in FIG. 22, each of the first quantum dot QD1 and the second quantum dot QD2 according to the second embodiment is a shell-less type constituted by the core cC that is crystalline. The inorganic matrix material Mx according to the present embodiment includes an amorphous portion and is in direct contact with the core cC. The amorphous portion of the inorganic matrix material Mx may be partially formed at the surface of the core cC or may completely cover the core cC. The crystalline body cB is the core cC, and the inorganic amorphous material aB is the amorphous portion of the inorganic matrix material Mx. The inorganic matrix material Mx fills a space between the crystalline body cB that is the core cC of the first quantum dot QD1 and the crystalline body cB that is the core cC of the second quantum dot QD2.

The inorganic amorphous material aB is formed at at least a part of the surface of the core cC of the first quantum dot QD1. The inorganic amorphous material aB may be formed at a portion of the surface facing the second quantum dot QD2. In other words, the inorganic amorphous material aB may be formed at at least a part of the surface of the core cC of the first quantum dot QD1 in the region K between the core cC of the first quantum dot QD1 and the core cC of the second quantum dot QD2. FIG. 22 does not limit the shape and size of the core cC, and does not limit the crystal type of the core cC.

### Example 3

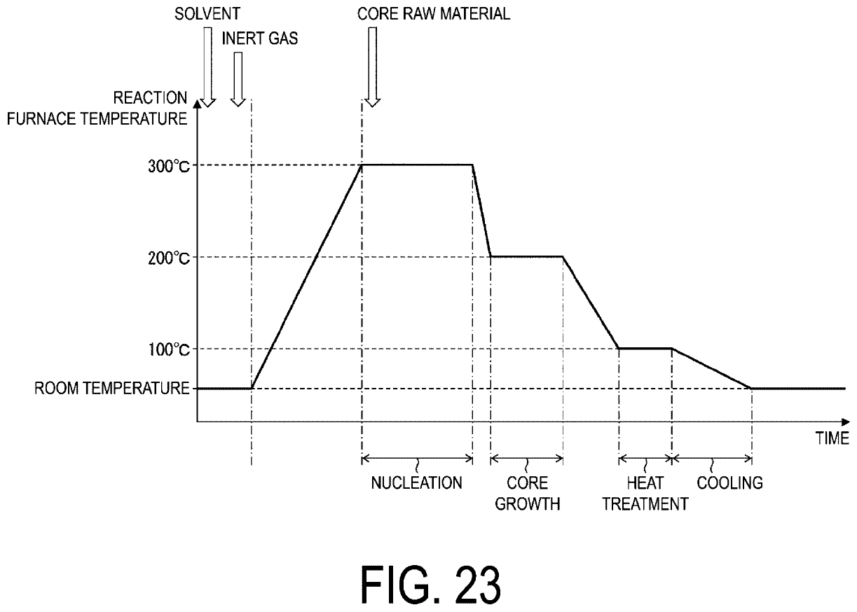

FIG. 23 is a time-series change diagram of a temperature of a reaction furnace used in a quantum dot manufacturing method according to Example 3 of the disclosure. Similarly to the arrows illustrated in FIG. 19, the arrows illustrated in FIG. 23 indicate time points at which a solvent, an inert gas, and a core raw material are charged into the reaction furnace. In the present embodiment, as illustrated in FIG. 23, the temperature of the reaction furnace was raised, lowered, and maintained while the above-described materials were charged into the reaction furnace.

The solvent was a mixture of trioctylphosphine oxide and hexadecylamine at a weight ratio of 2:1. The inert gas was argon (Ar). The core material was triethylindium and powdered phosphorus (P). The halogen material was fluoromethane or trifluoroacetic acid. Octylamine and bis(trimethylsilyl)sulfide are additives for stabilizing the synthesizing reaction by temporarily modifying a defect at the surface of the core or shell in the synthesizing process.

A substance amount of triethylindium is “a-1 [mol]”, a substance amount of the halogen raw material is “a-2 [mol]”, a substance amount of powdered phosphorus is “b [mol]”, a substance amount of octylamine is “c [mol]”, and a substance amount of bis(trimethylsilyl)sulfide is “d [mol]”. A substance amount ratio of the raw materials is a-1:a-2:b:c:d=10:0.01:9:7:3.

First, a solvent was charged into a reaction furnace, an inert gas was sealed therein, and a temperature of the reaction furnace was raised to 300 degrees Celsius and maintained. After the solvent was liquefied, the core material was injected into the reaction furnace by using a high-pressure injector to decompose the core material and then to produce seed crystals of the cores cC. Then, the temperature of the reaction furnace was then lowered to 200 degrees Celsius at a rate of 400° C./minute and maintained. The seed crystals were grown at a rate of 10 nm/200 minutes at 200 degrees Celsius.

Subsequently, the temperature of the reaction furnace was decreased to 100 degrees Celsius at a rate of 30 degrees Celsius/second or less and maintained at 100 degrees Celsius for 1 hour. Then, the temperature of the reaction furnace was decreased to room temperature at a rate of 50 degrees Celsius/second. The room temperature was 25 degrees Celsius.

As described above, the quantum dot QD including the core cC being crystalline and containing indium phosphide was manufactured.

### Third Embodiment

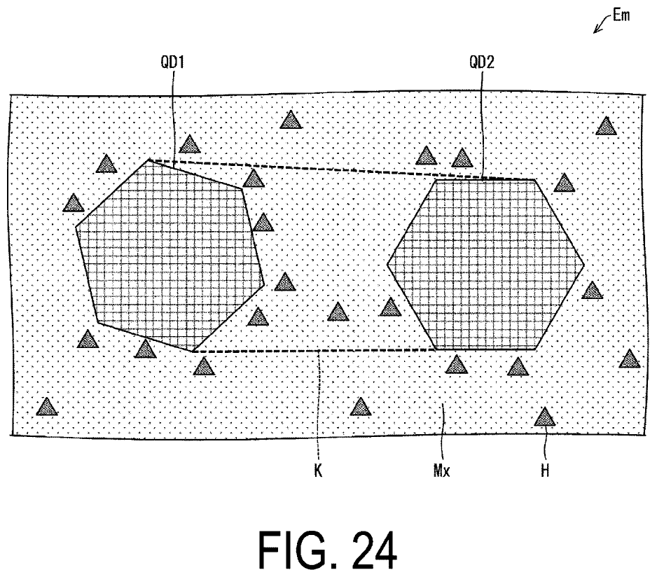

FIG. 24 is a cross-sectional view illustrating an example of a quantum dot layer according to a third embodiment. As illustrated in FIG. 24, the inorganic matrix material Mx may contain the halogen H. An average value in halogen concentration in the inorganic matrix material Mx may be 10¹⁶ [cm⁻³] to 10²⁰ [cm⁻³]. The halogen H may contain one or more among fluorine (F), chlorine (Cl), bromine (Br), and iodine (I).

FIG. 24 does not limit the shapes and sizes of the first quantum dot QD1 and the second quantum dot QD2, and does not limit the relationship between the first quantum dot QD1 and the second quantum dot QD2. Each of the first quantum dot QD1 and the second quantum dot QD2 according to the third embodiment may be a core-shell type including the shell aS that is amorphous, a multi-shell type, or a shell-less type.

When the halogen H is contained in the shell aS and the inorganic matrix material Mx, a halogen concentration in the shell aS may be equivalent to a halogen concentration in the inorganic matrix material Mx. Further, the halogen concentration in the shell aS may be higher or lower than the halogen concentration in the inorganic matrix material Mx. The halogen H contained in the shell aS may be the same as or different from the halogen H contained in the inorganic matrix material Mx.

By adding the halogen H to the quantum dot dispersion DL, the inorganic matrix material Mx can contain the halogen H. For example, fluoromethane or trifluoroacetic acid may be added to the quantum dot dispersion DL. In addition, when the material containing the halogen H is used as the precursor J and/or the solvent S, the inorganic matrix material Mx may contain the halogen H. For example, a metal halide such as zinc fluoride (ZnF₂) and zinc chloride (ZnCl₂) may be used as a part of the precursor J. For example, octane, or chlorobenzene may be used as the solvent S.

The halogen H may be a ligand coordinated to the quantum dot QD in the quantum dot dispersion DL or a part of the ligand. The halogen H may capture an unpaired electron in the inorganic matrix material Mx. The constituent atoms of the inorganic matrix material Mx are lost at random to generate defects in the inorganic matrix material Mx. For example, when the inorganic matrix material Mx contains group II-VI compounds, most of the deficiencies are deficiencies of group VI atoms, and unpaired electrons are generated. The halogen H captures an unpaired electron to close the shell at a site where the deficiency has occurred, leading to stabilization. As a result, the defect is stabilized, the carrier injection efficiency into the quantum dot QD is improved, and the EQE of the light-emitting element 1 is improved.

### Fourth Embodiment

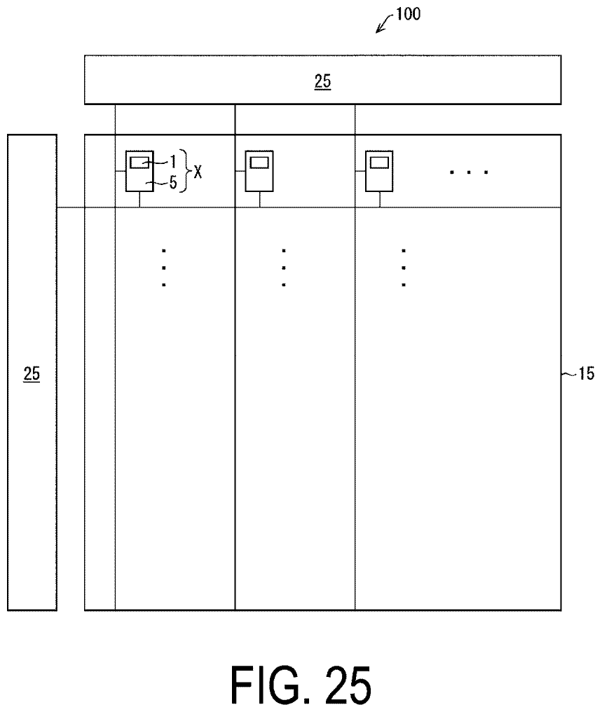

FIG. 25 is a schematic view illustrating an example of a display device according to an embodiment of the disclosure. As illustrated in FIG. 25, a display device 100 according to a fourth embodiment includes a display portion 15 including a plurality of subpixels X, and a driver circuit 25 for driving the display portion 15. At least one of the subpixels X includes the light-emitting element 1 and a pixel circuit 5. The light-emitting element 1 included in the display device 100 may be the light-emitting element 1 according to any one of the first to fourth embodiments described above, or may be a light-emitting element obtained by modifying or improving the light-emitting element 1 according to any one of the first to fourth embodiments described above.

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in each of the embodiments.

1. A light-emitting element comprising:
an anode and a cathode; and
a quantum dot layer positioned between the anode and the cathode, the quantum dot layer including a first quantum dot and a second quantum dot,
wherein the quantum dot layer includes a crystalline body serving as a core of the first quantum dot, and an inorganic amorphous material formed at at least a part of a surface of the crystalline body.

2. (canceled)

3. (canceled)

4. The light-emitting element according to claim 1,
wherein the inorganic amorphous material includes a shell of the first quantum dot.

5. The light-emitting element according to claim 4,
wherein the quantum dot layer includes an inorganic matrix material being in contact with the shell on an outer side of the shell.

6. The light-emitting element according to claim 5,
wherein the inorganic matrix material fills a space between the first quantum dot and the second quantum dot,
at least a part of a portion of the inorganic matrix material is amorphous, and the portion is in contact with the first quantum dot, and
the inorganic matrix material is made of a material different from a material of the shell.

7. The light-emitting element according to claim 1,
wherein the quantum dot layer includes an inorganic matrix material, and
the inorganic matrix material fills a space between the first quantum dot and the second quantum dot, at least a part of a portion of the inorganic matrix material is amorphous, and the portion is in contact with the first quantum dot.

8. (canceled)

9. The light-emitting element according to claim 1,
wherein the core of the first quantum dot includes a group III-V compound, and
the inorganic amorphous material includes a group II-VI compound.

10. The light-emitting element according to claim 1,
wherein an electron beam diffraction image including a halo pattern is obtained by irradiating the inorganic amorphous material with an electron beam.

11. The light-emitting element according to claim 1,
wherein a band gap of the inorganic amorphous material is larger than a band gap of the core of the first quantum dot.

12. The light-emitting element according to claim 1,
wherein the core of the first quantum dot includes indium phosphide, and
the inorganic amorphous material includes zinc sulfide.

13. The light-emitting element according to claim 1,
wherein the core of the first quantum dot includes indium phosphide, and
the inorganic amorphous material includes a mixed crystal of zinc sulfide and at least one of magnesium sulfide and lithium sulfide.

14. (canceled)

15. (canceled)

16. (canceled)

17. The light-emitting element according to claim 6,
wherein a band gap of the shell is equal to or larger than a band gap of the core of the first quantum dot, and
a band gap of the inorganic matrix material is equal to or larger than the band gap of the shell.

18. (canceled)

19. The light-emitting element according to claim 6,
wherein the shell includes a group II-VI compound,
the inorganic matrix material includes a group II-VI compound, and
at least one of a group II atom and a group VI atom included in the shell belongs to a higher period in a periodic table than a period of at least one of a group II-atom and a group VI atom included in the inorganic matrix material.

20. The light-emitting element according to claim 6,
wherein the core of the first quantum dot includes indium phosphide,
the shell includes zinc sulfide, and
the inorganic matrix material includes a mixed crystal of zinc sulfide and at least one of magnesium sulfide and lithium sulfide.

21. The light-emitting element according to claim 17,
wherein the shell and the inorganic matrix material includes a halogen, and
a halogen concentration in the shell is equivalent to a halogen concentration in the inorganic matrix material.

22. The light-emitting element according to claim 17,
wherein the shell and the inorganic matrix material includes a halogen, and
a halogen concentration in the shell is larger than a halogen concentration in the inorganic matrix material.

23. The light-emitting element according to claim 17,
wherein the shell and the inorganic matrix material includes a halogen, and
a halogen concentration in the shell is less than a halogen concentration in the inorganic matrix material.

24. (canceled)

25. The light-emitting element according to claim 1,
wherein the quantum dot layer includes a plurality of quantum dots including the first quantum dot and the second quantum dot, and
a quantum dot density in the quantum dot layer is from 1×10¹⁷ to 6×10¹⁷ [cm⁻³].

26. The light-emitting element according to claim 1,
wherein the quantum dot layer includes a plurality of quantum dots including the first quantum dot and the second quantum dot, and
an average particle diameter of the plurality of quantum dots is from 5 to 50 [nm].

27. (canceled)

28. A quantum dot manufacturing method comprising:
preparing a solution including a core being crystalline, a precursor of a group II-VI compound, and a solvent; and
heating the solution, thus causing the precursor to be modified into the group II-VI compound, and then primarily cooling the solution at a rate equal to or more than 100 degrees Celsius/second.

29. The quantum dot manufacturing method according to claim 28,
wherein after a temperature of the solution primarily cooled is maintained for a certain period of time, the solution is cooled slowly compared with the primary cooling.

30. (canceled)
